(19) United States
(12) Patent Application Publication
(10) Pub. No.: US 2007/0158720 A1
(43) Pub. Date: Jul. 12, 2007

(54) Semiconductor device with cells each having a trench capacitor and a switching transistor thereon

(76) Inventor: Takashi Izumida, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/408,966

(22) Filed: Apr. 24, 2006

(30) Foreign Application Priority Data
Jan. 12, 2006 (JP) 2006-005055

(51) Int. Cl. H01L 29/94

(52) U.S. Cl. 257/296

(57) ABSTRACT

A semiconductor device includes a semiconductor substrate, at least one trench capacitor which is buried into the surface area of the semiconductor substrate, and a first insulation film which is formed on the trench capacitor. The semiconductor device further includes at least one switching transistor provided on the surface of the semiconductor substrate which corresponds to the trench capacitor, the switching transistor having a body section set in an electrically floating state between source and drain regions, the first insulation film being interposed between the body section of the switching transistor and the trench capacitor opposed to one another, the trench capacitor being electrically connected to one of the source and drain regions of the switching transistor.

### CROSS-REFERENCE TO RELATED APPLICATIONS

This application is based upon and claims the benefit of priority from prior Japanese Patent Application No. 2006-005055, filed Jan. 12, 2006, the entire contents of which are incorporated herein by reference.

### BACKGROUND OF THE INVENTION

1. Field of the Invention

The present invention relates to a semiconductor device. More specifically, the invention relates to a dynamic random access memory (DRAM) and a DRAM-embedded semiconductor device.

2. Description of the Related Art

As is well-known, the memory cells of a DRAM (referred to as DRAM cells hereinafter) each include one switching metal oxide semiconductor field effect transistor (switching MOSFET) and one trench capacitor. DRAM cells each including a deep trench capacitor and a switching MOSFET thereon have already been known (see U.S. Pat. No. 6,472,702, K. Sunouchi et al., “A Surrounding Gate Transistor (SGT) Cell for 64/256 Mbit DRAMs,” IEDM 1989, and the like).

The above-described DRAM cells have the problem that the charges in the deep trench capacitor are easily decreased by leakage currents and thus the charge holding power of the deep trench capacitor is low. In a prior art silicon-on-insulator (SOI) DRAM and surrounding gate transistor (SGT) DRAM, a large amount of off-leakage current flows, thus decreasing the charge holding power of the deep trench capacitor.

### BRIEF SUMMARY OF THE INVENTION

According to a first aspect of the present invention, there is provided a semiconductor device comprising a semiconductor substrate, at least one trench capacitor which is buried into a surface area of the semiconductor substrate, a first insulation film which is formed on the trench capacitor, and at least one switching transistor provided on a surface of the semiconductor substrate which corresponds to the trench capacitor, the switching transistor having a body section set in an electrically floating state between source and drain regions, the first insulation film being interposed between the body section of the switching transistor and the trench capacitor opposed to one another, the trench capacitor being electrically connected to one of the source and drain regions of the switching transistor.

### BRIEF DESCRIPTION OF THE SEVERAL VIEWS OF THE DRAWING

FIG. 1 is a sectional view showing a configuration of a DRAM cell according to a first embodiment of the present invention;

FIG. 2 is a sectional view explaining a method of manufacturing the DRAM cell shown in FIG. 1;

FIG. 3 is a sectional view explaining the method of manufacturing the DRAM cell shown in FIG. 1;

FIG. 4 is a sectional view explaining the method of manufacturing the DRAM cell shown in FIG. 1;

FIG. 5 is a sectional view explaining the method of manufacturing the DRAM cell shown in FIG. 1;

FIG. 6 is a sectional view explaining the method of manufacturing the DRAM cell shown in FIG. 1;

FIG. 7 is a sectional view explaining the method of manufacturing the DRAM cell shown in FIG. 1;

FIG. 8 is a sectional view explaining the method of manufacturing the DRAM cell shown in FIG. 1;

FIG. 9 is a sectional view explaining the method of manufacturing the DRAM cell shown in FIG. 1;

FIG. 10 is a sectional view explaining the method of manufacturing the DRAM cell shown in FIG. 1;

FIG. 11 is a sectional view explaining the method of manufacturing the DRAM cell shown in FIG. 1;

FIG. 12 is a sectional view explaining the method of manufacturing the DRAM cell shown in FIG. 1;

FIG. 13 is a sectional view explaining the method of manufacturing the DRAM cell shown in FIG. 1;

FIG. 14 is a sectional view explaining the method of manufacturing the DRAM cell shown in FIG. 1;

FIG. 15 is a developed view of a double-gate MOSFET, explaining the thickness of an insulation film formed between a deep trench capacitor and a switching transistor;

FIG. 16 is a developed view of a DRAM cell, explaining the thickness of an insulation film formed between a deep trench capacitor and a switching transistor, taking the configuration shown in FIG. 1 as an example;

FIG. 17A is a sectional view explaining the arrangement of a contacting polysilicon layer and a drawing polysilicon region, taking the configuration shown in FIG. 1 as an example;

FIG. 17B is a plan view explaining the arrangement shown in FIG. 17A;

FIG. 18 is a plan view explaining the arrangement of a gate electrode and a drawing polysilicon region, taking the configuration shown in FIG. 1 as an example;

FIG. 19 is a sectional view showing a configuration of a DRAM cell according to a second embodiment of the present invention;

FIG. 20 is a sectional view explaining a method of manufacturing the DRAM cell shown in FIG. 19;

FIG. 21 is a sectional view explaining the method of manufacturing the DRAM cell shown in FIG. 19;

FIG. 22 is a sectional view explaining the method of manufacturing the DRAM cell shown in FIG. 19;

FIG. 23 is a sectional view explaining the method of manufacturing the DRAM cell shown in FIG. 19;

FIG. 24 is a sectional view explaining the method of manufacturing the DRAM cell shown in FIG. 19;

FIG. 25 is a sectional view explaining the method of manufacturing the DRAM cell shown in FIG. 19;

FIG. 26 is a sectional view explaining the method of manufacturing the DRAM cell shown in FIG. 19;

FIG. 27 is a sectional view explaining the method of manufacturing the DRAM cell shown in FIG. 19;

FIG. 28 is a sectional view explaining another method of manufacturing the DRAM cells shown in FIGS. 1 and 19, in which an insulation film is formed between a deep trench capacitor and a switching transistor;

FIG. 29 is a sectional view showing a configuration of a DRAM cell according to a third embodiment of the present invention;

FIG. 30 is a sectional view explaining a method of manufacturing the DRAM cell shown in FIG. 29;

FIG. 31 is a sectional view explaining the method of manufacturing the DRAM cell shown in FIG. 29;

FIG. 32 is a sectional view explaining the method of manufacturing the DRAM cell shown in FIG. 29;

FIG. 33 is a sectional view explaining the method of manufacturing the DRAM cell shown in FIG. 29;

FIG. 34 is a sectional view explaining the method of manufacturing the DRAM cell shown in FIG. 29;

FIG. 35 is a sectional view explaining the method of manufacturing the DRAM cell shown in FIG. 29;

FIG. 36 is a sectional view explaining the method of manufacturing the DRAM cell shown in FIG. 29;

FIG. 37 is a sectional view explaining the method of manufacturing the DRAM cell shown in FIG. 29;

FIG. 38 is a sectional view explaining the method of manufacturing the DRAM cell shown in FIG. 29;

FIG. 39 is a sectional view explaining the method of manufacturing the DRAM cell shown in FIG. 29;

FIG. 40 is a sectional view showing a configuration of a DRAM cell using a bulk silicon substrate according to another embodiment of the present invention; and

FIG. 41 is a sectional view showing a configuration of a DRAM cell using an SOI substrate according to still another embodiment of the present invention.

### DETAILED DESCRIPTION OF THE INVENTION

It should be noted that the drawings are schematic ones and the dimension ratios shown therein are different from the actual ones. The dimensions vary from drawing to drawing and so do the ratios of dimensions.

### First Embodiment

FIG. 1 shows a basic configuration of a memory cell (DRAM cell) of a semiconductor device (DRAM) according to a first embodiment of the present invention. The DRAM cell includes a bulk silicon substrate as a semiconductor substrate.

Referring to FIG. 1, the DRAM cell includes a switching transistor (switching MOSFET) ST immediately above a deep trench capacitor DT. A shallow trench isolation (STI) region 12 is formed in the surface area of a bulk silicon substrate 11. The deep trench capacitor DT is shaped like “T” in a sectional view and formed in the surface area of the substrate 11 which corresponds to the STI region 12. An insulation film (second insulation film) 13 is formed between the capacitor DT and the STI region 12. The deep trench capacitor DT includes a trench capacitor TC for storing charges and a drawing polysilicon region PS1 connected to the trench capacitor TC and serving as a storage node. The trench capacitor TC penetrates the bottom of the STI region 12 and is buried in the bulk silicon substrate 11 to a given depth. The drawing polysilicon region PS1 is provided to cover the surface of the STI region 12.

An insulation film (first insulation film) 14 is formed between the switching transistor ST and the deep trench capacitor DT. The switching transistor ST is so formed that its semiconductor layer (body section) 22 other than diffusion layers (source and drain regions) 21a and 21b is located almost immediately above the trench capacitor TC. The diffusion layers 21a and 21b have a lightly doped drain (LDD) structure. The switching transistor ST includes a gate electrode 24. The gate electrode 24 is formed on the surface of the body section 22, which corresponds to an area between the diffusion layers 21a and 21b, with a gate insulation film 23 interposed therebetween. A sidewall insulation film (sidewall) 25 is provided on either side of the gate insulation film 23 and gate electrode 24. A contacting polysilicon layer 26 is formed in one part of the diffusion layers 21a and 21b of the switching transistor ST and connected to the polysilicon region PS1. An insulation film 27 is provided to bury the switching transistor ST therein. The insulation film 27 includes a word line contact layer 28 connected to the top of the gate electrode 24 and a bit line contact layer 29 connected to the other part of the diffusion layers 21a and 21b.

The actual DRAM is composed of a plurality of DRAM cells so configured.

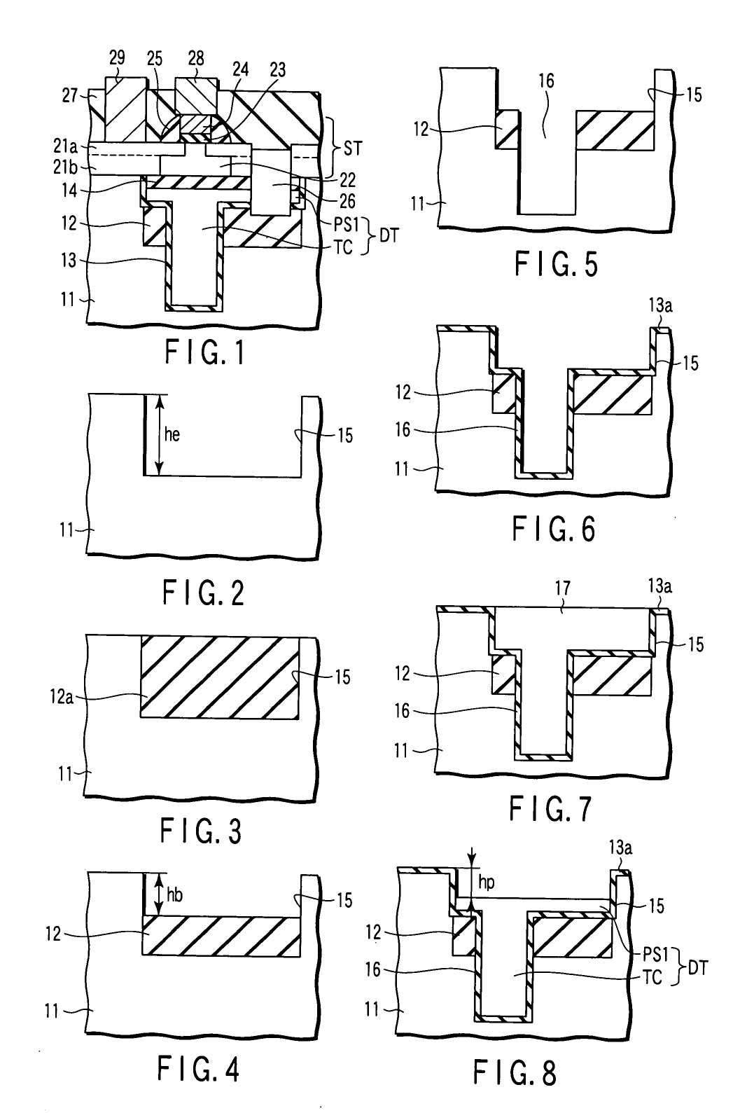

A process of manufacturing a DRAM cell having the above configuration will be described in brief. First, the surface area of a bulk silicon substrate 11 is etched until a recess 15 for forming an STI region 12 reaches a depth of he (FIG. 2). An insulation film 12a is deposited to fill the recess 15 and then flattened (FIG. 3). As the insulation film 12a, for example, a silicon oxide (SiO₂) film is employed. The insulation film 12a is etched until the recess 15 reaches a depth of hb to form the STI region 12 (FIG. 4).

The STI region 12 is partly subjected to selective etching to form a trench 16 for forming a deep trench capacitor DT (FIG. 5). In order to form an insulation film 13 on the inner wall of the trench 16 and that of the recess 15, an insulation film 13a is deposited on the entire structure (FIG. 6). As the insulation film 13a, for example, a silicon nitride (SiN) film is employed. The recess 15 and trench 16 are filled with a polysilicon film 17 with the insulation film 13a interposed therebetween, and the polysilicon film 17 is flattened (FIG. 7). The polysilicon film 17 is etched until the recess 15 reaches a depth of hp (hp<hb) to form a trench capacitor TC and a polysilicon region PS1, both of which serve as the deep trench capacitor DT (FIG. 8).

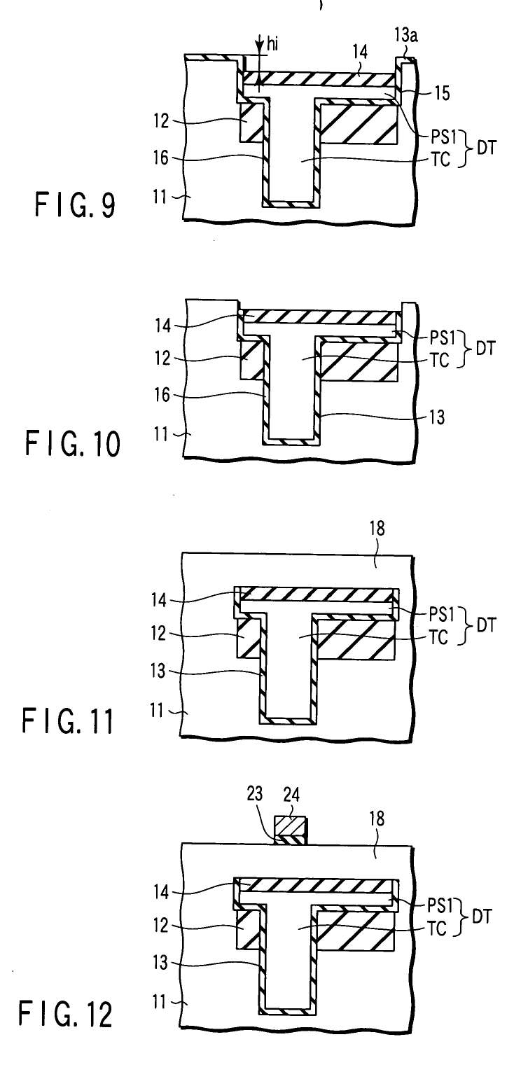

An insulation film is deposited on the entire cell and flattened. Then, the structure is etched until the recess 15 reaches a depth of hi (hi<hp) to form an insulation film 14 having a desired thickness (FIG. 9). As the insulation film 14, for example, a silicon oxide (SiO₂) film is employed. The insulation film 13a is separated from the surface of the bulk silicon substrate 11 to complete the insulation film 13 (FIG. 10). A silicon film 18 that is to serve as a semiconductor layer is epitaxially grown on the entire cell (FIG. 11). Element isolation regions (not shown) are formed in the silicon film 18 and a gate insulation film 23 and a gate electrode 24 for the switching transistor ST are formed on the silicon film 18 (FIG. 12) and, in this case, the gate electrode 24 is formed immediately above the trench capacitor TC.

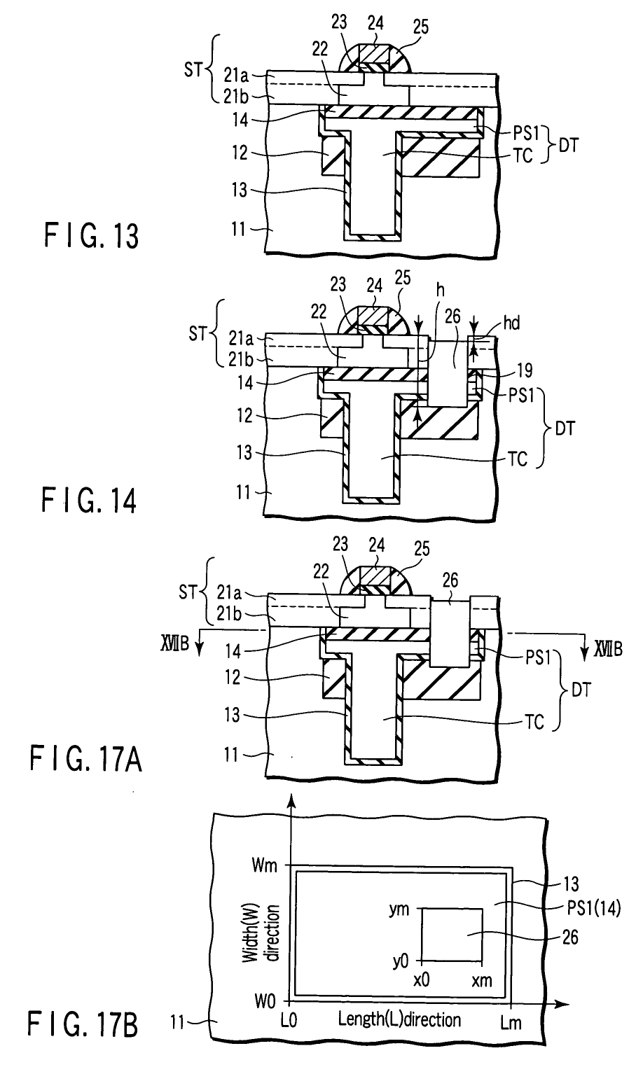

Using the gate electrode 24 as a mask, a diffusion layer 21a is formed in the silicon film 18. A sidewall insulation film 25 is formed on each sidewall of the gate insulation film 23 and gate electrode 24. Using the gate electrode 24 and the sidewall insulation film 25 as a mask, a diffusion layer 21b is formed (FIG. 13). The diffusion layers 21a and 21b are therefore formed leaving a body section 22 in the silicon film 18. One part of the diffusion layers 21a and 21b is etched to cause the insulation film 14, drawing polysilicon region PS1 and insulation film 13 to penetrate therethrough, and a trench 19 is formed to a depth of h (he>h) in the STI region 12. A polysilicon film is deposited to fill the trench 19 and then over-etched until the trench 19 reaches a depth of hd, thus forming a contacting polysilicon layer 26 (FIG. 14). Finally, an insulation film 27 is deposited on the entire cell and flattened to form a word line contact 28 and a bit line contact 29. Consequently, the DRAM cell shown in FIG. 1 is completed.

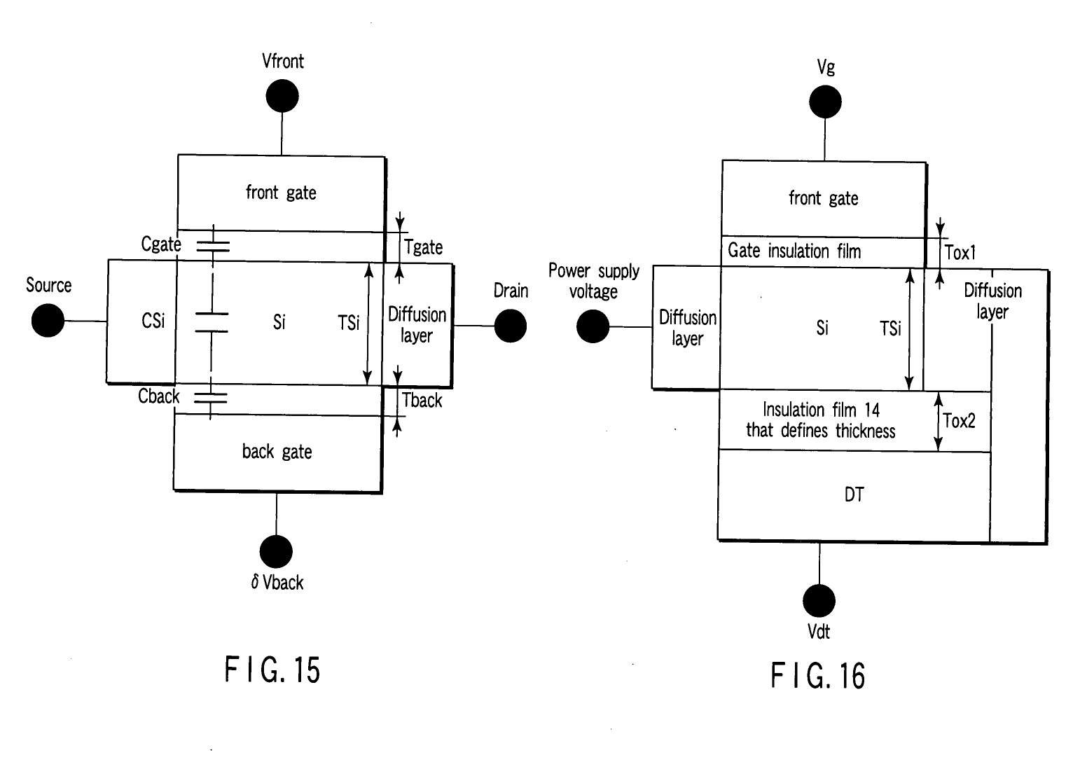

The thickness of the insulation film 14 in the DRAM cell according to the first embodiment will be described. FIG. 15 shows a double-gate MOSFET having a back gate to explain the control of a threshold value. Assuming that a variation in back gate voltage is δ Vback, a variation in threshold value is δ Vth, the capacity of silicon (Si) is CSi, the capacity of the back gate is Cback, and the capacity of the front gate is Cgate, the threshold value of the double gate MOSFET (the ratio of δ Vback between δ Vth) is represented by the following equation (1):
−δVth/δVback=CSi·Cback/[Cgate(CSi+Cback)] (1)

If the above equation (1) is expressed by dielectric constant ε and thickness T on the assumption that the area of silicon, that of the back gate and that of the front gate are the same, the following equation (2) is given:

$$- δ Vth / δ Vback = \frac{ɛ Si}{YSi} \frac{ɛ back}{Tback} / [ \frac{ɛ gate}{Tgate} ( \frac{ɛ Si}{YSi} + \frac{ɛ back}{Tback} ) ] \qquad ( 2 )$$

If the above equation (2) is rewritten with respect to thickness Tback of the back gate, the following equation (3) is given:

$$Tback = \frac{ɛ back}{ɛ gate} Tgate ( \frac{- δ Vback}{δ Vth} ) - \frac{ɛ back}{ɛ Si} TSi \qquad ( 3 )$$

Assuming that, on the basis of the above, the gate voltage of the DRAM of the first embodiment is Vg and a difference in potential between charges storing state “1” and non-changes storing state “0” in the deep trench capacitor DT is Vdt as shown in FIG. 16, the following equations (4) and (5) are given:

$$\begin{matrix}\begin{matrix}Tox 1 = Tgate \\ ɛ gate = ɛ ox 1 \\ Tox 2 = Tback \\ ɛ ox 2 = ɛ back \\ TSi = TSi \\ ɛ Si = ɛ Si \\ Vdt = δ Vback\end{matrix} \} & ( 4 ) \\ Tox 2 = \frac{ɛ ox 2}{ɛ ox 1} Tox 1 ( \frac{- Vdt}{δ Vth} ) - \frac{ɛ ox 2}{ɛ Si} TSi & ( 5 )\end{matrix}$$

where Tox1 is the thickness of the gate insulation film 23, εox1 is the dielectric constant of the gate insulation film 23, Tox2 is the thickness of the insulation film 14 between the deep trench capacitor DT and the switching transistor ST, εox2 is the dielectric constant of the insulation film 14, TSi is the thickness of the semiconductor layer (silicon film) 18 corresponding to the body section 22, and εSi is the dielectric constant of the semiconductor layer 18.

Assuming here that a ground voltage is supplied to a plate electrode coupled to the deep trench capacitor DT and the positive charges are stored in the deep trench capacitor DT. If an adequate voltage to reduce off-currents Ioff is δ Vth≦−0.1 Vg where Vdt=Vg=power supply voltage, the thickness Tox2 of the insulation film 14 is defined by the following equation (6):

$$Tox 1 ≦ Tox 2 \leq 10 \frac{ɛ ox 2}{ɛ ox 1} Tox 1 - \frac{ɛ ox 2}{ɛ Si} TSi \qquad ( 6 )$$

Particularly when εox1=εox2=εox(⅓)εSi (the relative dielectric constant of SiO₂ is 3.9 and that of Si is 11.9), the thickness Tox2 of the insulation film 14 is defined by the following equation (7):

$$Tox 1 ≦ Tox 2 \leq 10 Tox 1 - \frac{1}{3} TSi \qquad ( 7 )$$

If the power supply voltage is supplied to the plate electrode with the result that the negative charges are stored in the deep trench capacitor DT and Vdt=−Vg=−(power supply voltage), the threshold value of the MOSFET is displaced to cause off-currents Ioff to flow and accordingly increase leakage currents. In this case, the thickness Tox2 of the insulation film 14 is defined by the following equation (8):

$$Tox 2 \geq 10 \frac{ɛ ox 2}{ɛ ox 1} Tox 1 - \frac{ɛ ox 2}{ɛ Si} TSi \qquad ( 8 )$$

As described above, the thickness of the insulation film 14 between the deep trench capacitor DT and the switching transistor ST is optimized according to whether the charges to be stored in the deep trench capacitor DT are positive or negative, with the result that the charge holding power of the deep trench capacitor DT can be improved. In the DRAM cell so configured that the switching transistor ST is provided immediately above the deep trench capacitor DT, the charges of the deep trench capacitor DT can efficiently have the substrate bias effect on the body section 22 by optimizing the thickness of the insulation film 14. Thus, the threshold value of the switching transistor ST can be controlled (increased) when the deep trench capacitor DT holds charges, and the off-currents Ioff can be decreased. Consequently, charge leakage in off-current state can be reduced, and the charge holding power of the deep trench capacitor DT can be prevented from lowering.

In the first embodiment, for example, the body section 22 of the switching transistor ST is surrounded by the diffusion layers 21a and 21b and the insulation film 14. If the body section 22 is set in an electrically floating state, the substrate bias effect causes charges to be stored in the body section 22 and thus becomes more profound.

As illustrated in FIGS. 17A and 17B, the contacting polysilicon layer 26 (having a width of y0−ym and a length of x0−xm) is provided within the drawing polysilicon region PS1 (having a width of W0−Wm and a length of L0−Lm) (L0<x0, xm<Lm, W0<y0, ym<Wm). The contacting polysilicon layer 26 and the drawing polysilicon region PS1 are used to connect the diffusion layers 21a and 21b and the deep trench capacitor DT as a connecting portion and store charges in the deep trench capacitor DT. Therefore, the contacting polysilicon layer 26 can be prevented from contacting the bulk silicon substrate 11, and the charges that flow from the diffusion layers 21a and 21b to the deep trench capacitor DT can be prevented from escaping toward the bulk silicon substrate 11. FIG. 17A is a sectional view corresponding to FIG. 14, and FIG. 17B is a plan view taken along line XVIIB-XVIIB of FIG. 17A.

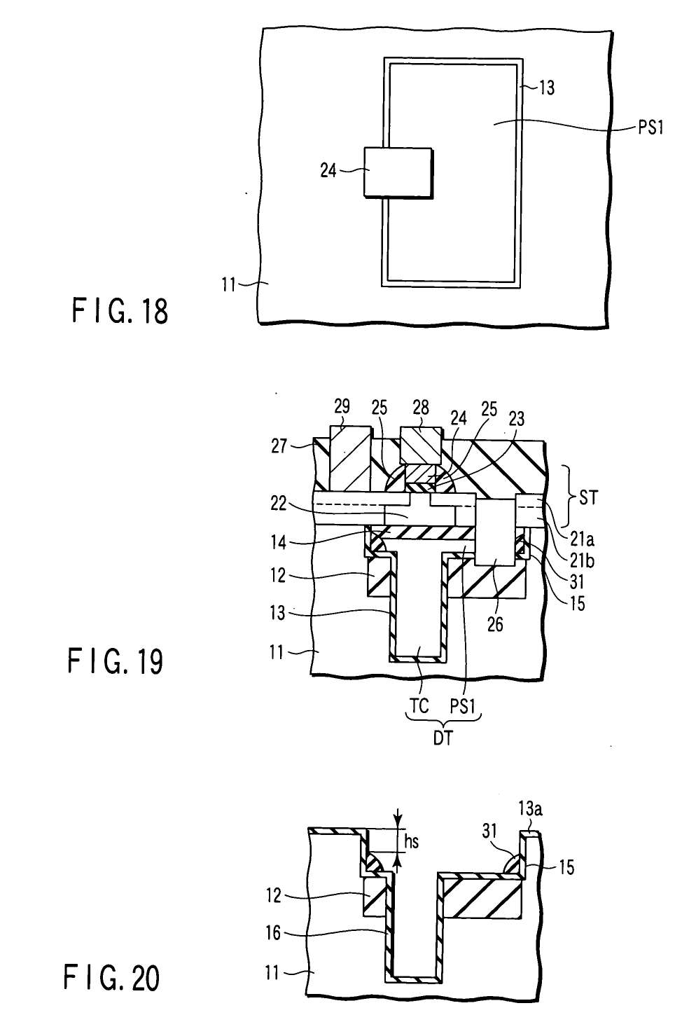

As illustrated in FIG. 18, the gate electrode 24 has only to overlap at least the storage node (drawing polysilicon region PS1). It is important to locate the deep trench capacitor DT almost immediately under the body section 22. If the distance between the body section 22 and the deep trench capacitor DT is the shortest, the substrate bias effect can be exerted on the body section 22 more efficiently.

If the length (L0−Lm) of the drawing polysilicon region PS1 is set greater than the width (W) of the gate electrode 24, the substrate bias effect can be exerted uniformly on the body section 22 in its width (W) direction. It is thus possible to eliminate the bias of an electric field in the body section 22, which is caused by the charges supplied from the deep trench capacitor DT.

If the length (L0−Lm) of the drawing polysilicon region PS1 is set greater than the length (L) of the gate electrode 24, the substrate bias effect can be exerted uniformly on the body section 22 in its length (L) direction.

In the DRAM cell of the first embodiment, the substrate bias effect obtained through the insulation film 14 is greater than that obtained through the STI region 12 in terms of film thickness and dielectric constant. Since the effective thickness of the insulation film 14 is not greater than the effective width of the STI region 12, the substrate bias effect obtained by the charges supplied from the deep trench capacitor DT immediately under the body section 22 can be dominant over a parasitic substrate bias effect obtained from the deep trench capacitor DT of adjacent cells.

In the first embodiment, the silicon film 18 serving as a semiconductor layer is formed by epitaxial growth (FIG. 11). The present invention is not limited to this formation. For example, the silicon film 18 can be formed more uniformly by recrystallization after an SOI structure is obtained by depositing a polysilicon layer or an amorphous silicon layer.

### Second Embodiment

FIG. 19 shows a basic configuration of a (memory cell) DRAM cell of a semiconductor device (DRAM) according to a second embodiment of the present invention. The DRAM cell includes a bulk silicon substrate as a semiconductor substrate. The same components as those of the first embodiment are denoted by the same reference numerals and their detailed descriptions are omitted.

Referring to FIG. 19, a sidewall 31 is formed on the inner side of an insulation film 13 formed on the inner wall of a recess 15 to increase the insulativeness between a drawing polysilicon region PS1 and a bulk silicon substrate 11 thereof and thus virtually lengthen the distance therebetween.

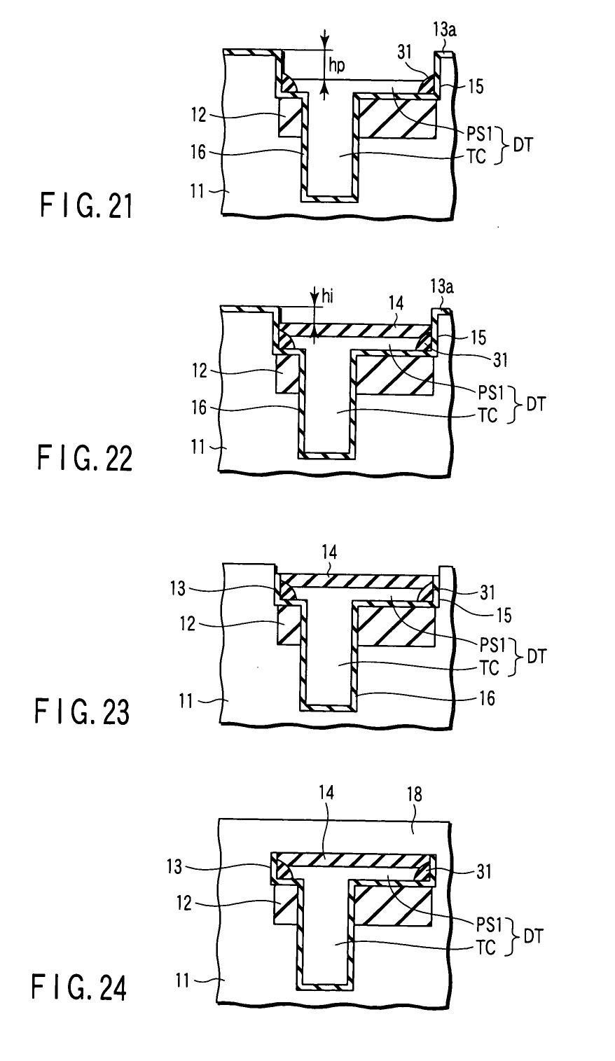

A process of manufacturing a DRAM cell according to the second embodiment will be described in brief. Since the process is the same as that of the first embodiment until after a step of depositing an insulation film 13a on the entire cell in order to form an insulation film 13 on the inner wall of a trench 16 and that of a recess 15 (FIGS. 2 to 6), its subsequent steps will be described. After the insulation film 13a is deposited, another insulation film is deposited thereon. In the recess 15, a sidewall 31 is formed without being formed to the depth of hs (hs<hp) from the top surface of the cell (FIG. 20). The trench 16 and the recess 15 are filled with a polysilicon film, with the insulation film 13a and the sidewall 31 interposed therebetween, and the polysilicon film is flattened. The polysilicon film is etched until the depth of the recess 15 reaches hp (hs<hp) to form a trench capacitor TC and a drawing polysilicon region PS1, which are to serve as a deep trench capacitor DT (FIG. 21).

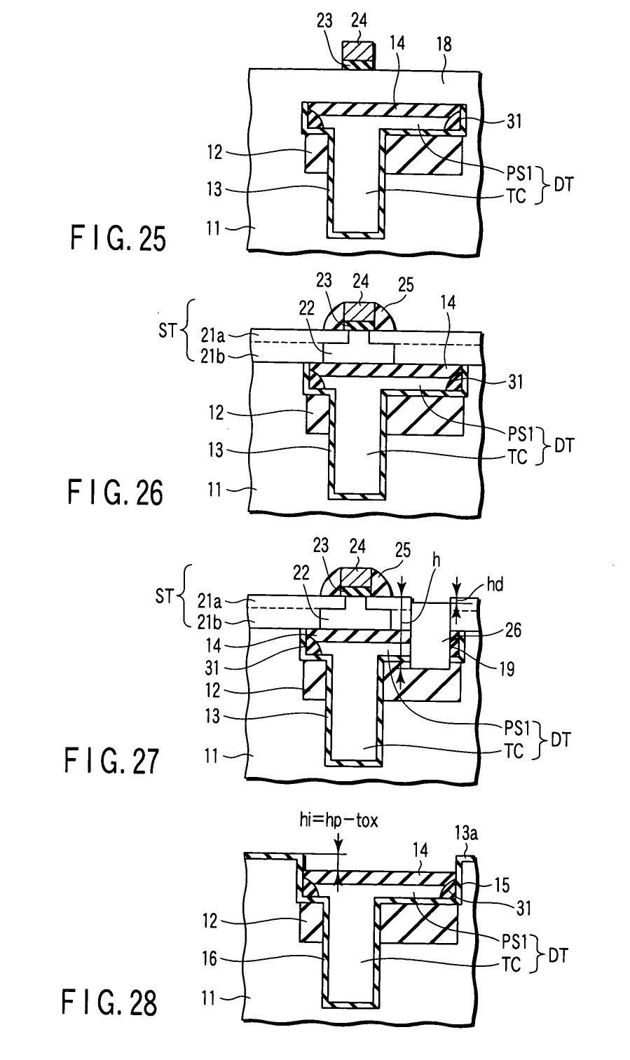

An insulation film is deposited on the entire cell and flattened. Then, it is etched until the depth of the recess 15 reaches hi (hi<hs) to form an insulation film 14 having a desired thickness (FIG. 22). For example, silicon oxide (SiO₂) is used as the insulation film 14. The insulation film 13a is separated from the surface of the bulk silicon substrate 11 to complete the insulation film 13 (FIG. 23). A silicon film 18 that is to serve as a semiconductor layer is epitaxially grown on the entire cell (FIG. 24). On the silicon film 18, a gate insulation film 23 and a gate electrode 24 are formed for a switching transistor ST (FIG. 25). The gate electrode 24 is formed immediately above the trench capacitor TC.

Using the gate electrode 24 as a mask, a diffusion layer 21a is formed in the silicon film 18. A sidewall insulation film 25 is formed on the sidewalls of the gate electrode 24 and gate insulation film 23. Using the sidewall insulation film 25 and gate electrode 24 as a mask, a diffusion layer 21b is formed (FIG. 26). Accordingly, the diffusion layers 21a and 21b are formed leaving a body section 22 in the silicon film 18. A trench 19 is formed by etching in one part of the diffusion layers 21a and 21b through the insulation film 14, drawing polysilicon region PS1 and insulation film 13. The trench 19 is formed to such a depth of h (he>h) as to reach an STI region 12. A polysilicon film is deposited to fill the trench 19 and then over-etched until the depth of the trench 19 becomes hd, thus forming a contacting polysilicon film 26 (FIG. 27). Finally, an insulation film 27 is deposited on the entire cell and flattened to form a word line contact 28 and a bit line contact 29. Consequently, the DRAM cell shown in FIG. 19 is completed.

In the above configuration of the second embodiment, too, the thickness of the insulation film 14 between the deep trench capacitor DT and the switching transistor ST is optimized according to whether the charges to be stored in the deep trench capacitor DT are positive or negative, with the result that the charge holding power of the deep trench capacitor DT can be improved.

Particularly when the sidewall 31 is formed on the inner side of the insulation film 13 formed on the inner wall of the recess 15, the parasitic capacitance between the drawing polysilicon region PS1 and the bulk silicon substrate 11 can be decreased. Accordingly, the charges between the body section 22 and the drawing polysilicon region PS1 (or deep trench capacitor DT) can be increased.

In the second embodiment, the silicon film 18 serving as a semiconductor layer is formed by epitaxial growth (FIG. 24). The present invention is not limited to this formation. For example, the silicon film 18 can be formed more uniformly by recrystallization after an SOI structure is obtained by depositing a polysilicon layer or an amorphous silicon layer.

In the first and second embodiments, as shown in FIG. 28, the surface of the drawing polysilicon region PS1 can be oxidized by thermal oxidation to form the insulation film 14. In this case, the depth hi is controlled in accordance with the thickness (tox) of an oxide film that is to serve as the insulation film 14 (hi=hp−tox). This configuration can improve the quality of an interface between the drawing polysilicon region PS1 and the insulation film 14.

In both of the first and second embodiments, the insulation film 14 is not limited to a single-layer film. For example, a multilayer film such as an ONO (oxide/nitride/oxide) film can be used as the insulation film 14.

In both of the first and second embodiments, a high-dielectric film such as a HfAlO film and a SiN film can be used as the insulation film 14. Using the high-dielectric film, the physical thickness of the insulation film 14 can be increased and thus its control can be simplified. In other words, an influence of variations in thickness can be lessened.

In both of the first and second embodiments, metal such as aluminum (Al), tungsten (W), nickel (Ni) and copper (Cu) can be used for the contacting polysilicon layer 26. The resistance of the contacting polysilicon layer 26 can thus be lowered more greatly.

In both of the first and second embodiments, the insulation film 12a for forming the STI region 12 is not limited to a SiO₂ film. For example, a low-dielectric film such as a porous film can be used. When a low-dielectric film is used for the STI region 12, the parasitic capacitance between the drawing polysilicon region PS1 (or deep trench capacitor DT) and the bulk silicon substrate 11 can be lowered.

In both of the first and second embodiments, for example, a SiO₂ film, a SiON film, and a high-dielectric film can be used as the gate insulation film 23.

### Third Embodiment

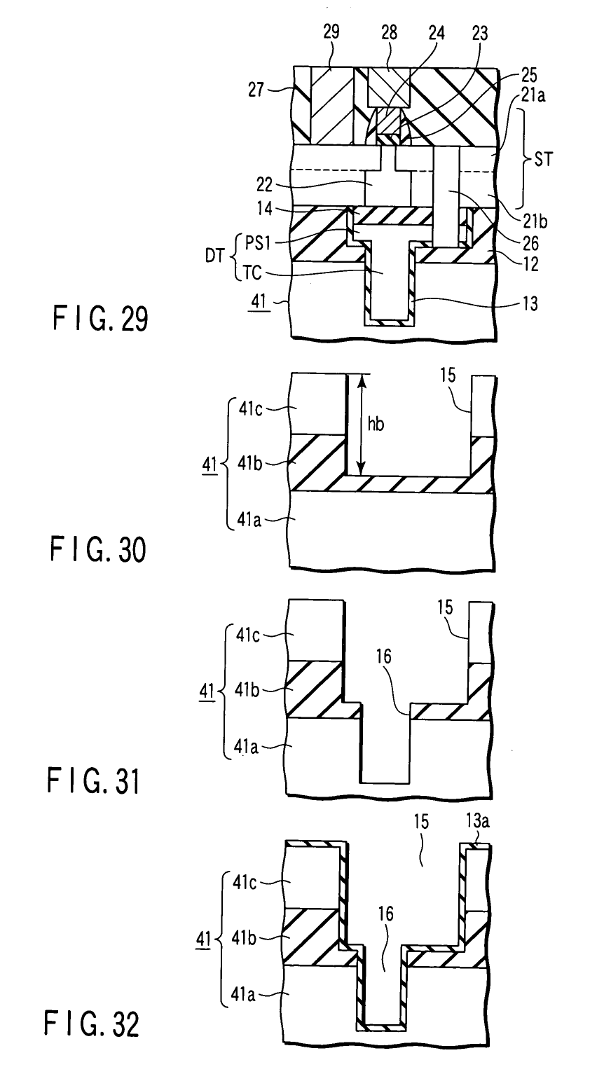

FIG. 29 shows a basic configuration of a memory cell (DRAM cell) of a semiconductor device (DRAM) according to a third embodiment of the present invention. The DRAM cell includes an SOI substrate as a semiconductor substrate. The same components as those of the first embodiment are denoted by the same reference numerals and their detailed descriptions are omitted.

In the third embodiment, as shown in FIG. 29, a DRAM cell is manufactured using an SOI substrate 41. This DRAM cell can be manufactured more simply than a DRAM cell to be manufactured using a bulk silicon substrate.

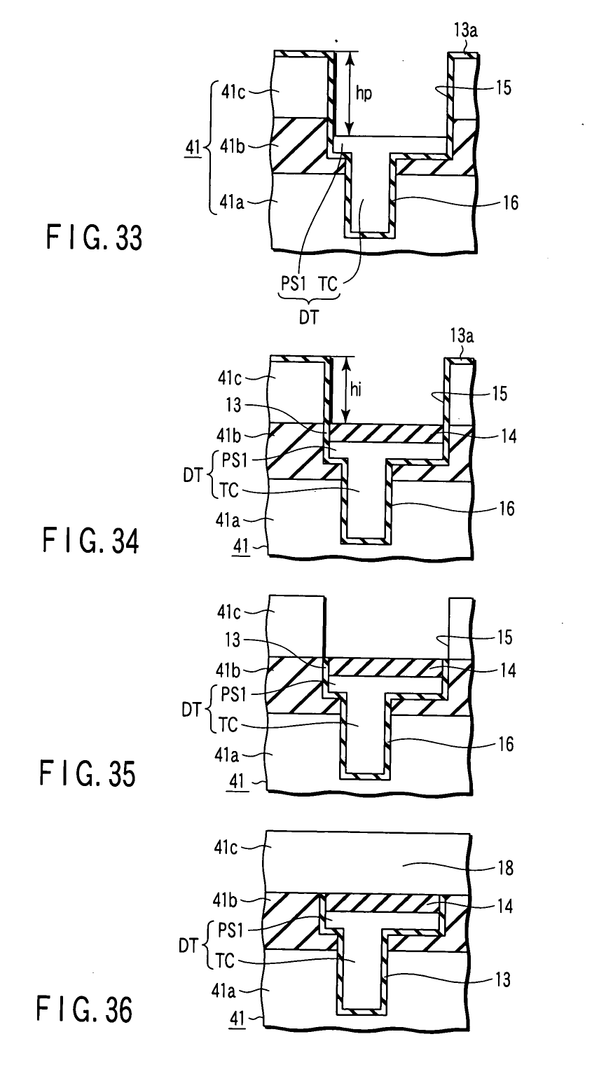

A process of manufacturing a DRAM cell according to the third embodiment will be described in brief. The surface area of the SOI substrate 41 is etched until the depth of a recess 15 for forming the drawing polysilicon region PS1 becomes hb (FIG. 30). The recess 15 penetrates an SOI layer 41c in the surface area of the SOI substrate 41 and reaches its underlying Burying Oxide isolation (BOX) layer 41b. The bottom of the recess 15 is subjected to selective etching to form a trench 16 for forming a trench capacitor TC (FIG. 31). The trench 16 reaches the silicon layer 41a under the BOX layer 41b. In order to form the insulation film 13 on the inner wall of the trench 16 and that of the recess 15, the insulation film 13a is deposited on the entire cell (FIG. 32). For example, a silicon nitride film (SiN) is used as the insulation film 13a. The trench 16 and recess 15 are filled with a polysilicon film with the insulation film 13a interposed therebetween, and the polysilicon film is flattened. Then, the polysilicon film is etched until the depth of the recess 15 becomes hp (hp<hb) to form a trench capacitor TC and a drawing polysilicon region PS1, which are to serve as a deep trench capacitor DT (FIG. 33).

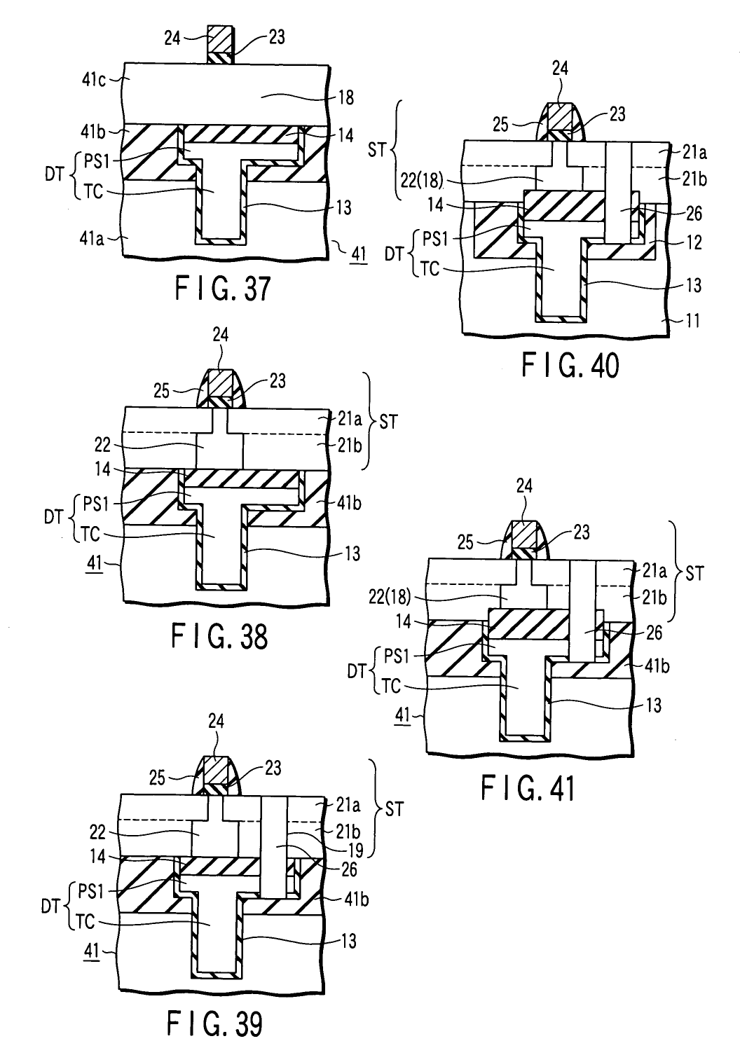

An insulation film is deposited on the entire cell and then flattened. After that, the insulation film is etched until the depth of the recess 15 becomes hi (hi<hp) to form an insulation film 14 having a desired thickness (FIG. 34). For example, silicon oxide (SiO₂) is used as the insulation film 14. The insulation film 13a is separated from the surface of the SOI substrate 41 to complete the insulation film 13 (FIG. 35). A silicon film 18 that is to serve as a semiconductor layer is epitaxially grown on the insulation film 14 to fill the recess 15 (FIG. 36). On the silicon film 18, a gate insulation film 23 and a gate electrode 24 are formed for a switching transistor ST (FIG. 37). The gate electrode 24 is formed immediately above the trench capacitor TC.

Using the gate electrode 24 as a mask, a diffusion layer 21a is formed in the silicon film 18 and SOI layer 41c. A sidewall insulation film 25 is formed on the sidewalls of the gate electrode 24 and gate insulation film 23. Using the sidewall insulation film 25 and gate electrode 24 as a mask, a diffusion layer 21b is formed (FIG. 38). Accordingly, the diffusion layers 21a and 21b are formed leaving a body section 22 in the silicon film 18 and SOI layer 41c. A trench 19 is formed by etching in one part of the diffusion layers 21a and 21b through the insulation film 14, drawing polysilicon region PS1 and insulation film 13. The trench 19 is formed to reach the BOX layer 41b. A polysilicon film is deposited to fill the trench 19 and then etched to form a contacting polysilicon film 26 (FIG. 39). Finally, an insulation film 27 is deposited on the entire cell and flattened to form a word line contact 28 and a bit line contact 29. Consequently, the DRAM cell shown in FIG. 29 is completed.

In the configuration of the third embodiment, too, the thickness of the insulation film 14 between the deep trench capacitor DT and the switching transistor ST is optimized according to whether the charges to be stored in the deep trench capacitor DT are positive or negative, with the result that the charge holding power of the deep trench capacitor DT can be improved.

In particular, the BOX layer 41b of the SOI substrate 41 is used as an STI region. A process for forming the STI region can be omitted.

Needless to say, various modifications can be applied to the DRAM cell according to the third embodiment as well as the DRAM cells according to the first and second embodiments.

In the DRAM cell using a bulk silicon substrate and the DRAM cell using an SOI substrate, the thickness of the semiconductor layer 18, which serves as the body section 22 of the switching transistor ST, can easily be controlled in accordance with the thickness of each of the insulation film 14 and the drawing polysilicon region PS1, as shown in, for example, FIGS. 40 and 41. In each of the embodiments, the thickness of the semiconductor layer 18 on the insulation film 14 is smaller than that of the semiconductor layer 18 (or SOI layer 41c) except on the insulation film 14; therefore, the parasitic resistance can be lowered more greatly.

In the above embodiments, the DRAM cell can be not only of an NMOS type, but also a PMOS type whose charge polarity is opposite to that of the NMOS type. In the above embodiments, the present invention is applied to a DRAM; however, it can be applied to various DRAM-embedded semiconductor devices.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
at least one trench capacitor which is buried into a surface area of the semiconductor substrate;
a first insulation film which is formed on the trench capacitor; and
at least one switching transistor provided on a surface of the semiconductor substrate which corresponds to the trench capacitor, the switching transistor having a body section set in an electrically floating state between source and drain regions,
the first insulation film being interposed between the body section of the switching transistor and the trench capacitor opposed to one another, the trench capacitor being electrically connected to one of the source and drain regions of the switching transistor.

2. The semiconductor device according to claim 1, wherein the trench capacitor and the switching transistor compose a memory cell.

3. The semiconductor device according to claim 2, wherein a connecting portion between the trench capacitor and the one of the source and drain regions of the switching transistor serves a charge storage node of the memory cell.

4. The semiconductor device according to claim 3, wherein the connecting portion exerts a substrate bias effect on the body section of the switching transistor.

5. The semiconductor device according to claim 1, wherein a thickness of the first insulation film is defined by the following equation when the charges stored in the trench capacitor are positive:
$$Tox 1 ≦ Tox 2 \leq 10 \frac{ɛ ox 2}{ɛ ox 1} Tox 1 - \frac{ɛ ox 2}{ɛ Si} TSi$$
where Tox1 is a thickness of a gate insulation film of the switching transistor, εox1 is a dielectric constant of the gate insulation film, Tox2 is a thickness of the first insulation film, εox2 is a dielectric constant of the first insulation film, TSi is a thickness of a semiconductor layer corresponding to the body section of the switching transistor, and εSi is a dielectric constant of the semiconductor layer.

6. The semiconductor device according to claim 1, wherein a thickness of the first insulation film is defined by the following equation when the charges stored in the trench capacitor are negative:
$$Tox 2 \geq 10 \frac{ɛ ox 2}{ɛ ox 1} Tox 1 - \frac{ɛ ox 2}{ɛ Si} TSi$$
where Tox1 is a thickness of a gate insulation film of the switching transistor, εox1 is a dielectric constant of the gate insulation film, Tox2 is a thickness of the first insulation film, εox2 is a dielectric constant of the first insulation film, TSi is a thickness of a semiconductor layer corresponding to the body section of the switching transistor, and εSi is a dielectric constant of the semiconductor layer.

7. The semiconductor device according to claim 1, wherein a connecting portion between the trench capacitor and the one of the source and drain regions of the switching transistor does not contact the semiconductor substrate other than the one of the source and drain regions.

8. The semiconductor device according to claim 1, further comprising at least one shallow trench isolation (STI) region which is buried into the surface area of the semiconductor substrate and surrounding the trench capacitor

9. The semiconductor device according to claim 1, further comprising a semiconductor layer in which the body section of the switching transistor is formed, the semiconductor layer including one of an epitaxially-grown layer of silicon and a deposited layer of polysilicon or amorphous silicon.

10. The semiconductor device according to claim 7, wherein the connecting portion includes a drawing portion formed below the first insulation film and a contacting portion formed to penetrate through the first insulation film.

11. The semiconductor device according to claim 10, further comprising a second insulation film between the drawing portion and the semiconductor substrate.

12. The semiconductor device according to claim 11, wherein the second insulation film includes one of a single-layer film and a multilayer film.

13. The semiconductor device according to claim 1, wherein the first insulation film is a single-layer including one of a silicon oxide film, a thermal oxide film, and a high-dielectric film or a multilayer film.

14. The semiconductor device according to claim 10, wherein the contacting portion is formed using metal materials.

15. The semiconductor device according to claim 8, wherein the shallow trench isolation region includes one of a silicon oxide film and a low-dielectric film.

16. The semiconductor device according to claim 1, wherein the semiconductor substrate is a bulk silicon substrate.

17. The semiconductor device according to claim 8, wherein the semiconductor substrate is a silicon-on-insulator substrate having a silicon-on-insulator structure, and the shallow trench isolation region is a Burying Oxide isolation (BOX) layer of the silicon-on-insulator substrate.

18. The semiconductor device according to claim 8, wherein the first insulation film is provided to protrude toward a semiconductor layer in which the body section of the switching transistor is formed from the shallow trench isolation region.

19. The semiconductor device according to claim 1, wherein the trench capacitor and the switching transistor compose a memory cell, and memory cells compose a dynamic random access memory.

20. The semiconductor device according to claim 1, wherein the trench capacitor and the switching transistor compose a memory cell, and memory cells compose an embedded dynamic random access memory.
